(19) United States
(12) Patent Application Publication
(10) Pub. No.: US 2011/0300712 A1
(43) Pub. Date: Dec. 8, 2011

(54) Methods of Forming a Photoresist Pattern Using Plasma Treatment of Photoresist Patterns

(76) Inventors: Kyoung-Mi Kim, Anyang-si (KR); Jeong-Ju Park, Hwaseong-si (KR); Mi-Ra Park, Seoul (KR); Bo-Hee Lee, Gunpo-si (KR); Jae-Ho Kim, Yongin-si (KR); Young-Ho Kim, Yongin-si (KR)

(21) Appl. No.: 13/103,375

(22) Filed: May 9, 2011

(30) Foreign Application Priority Data
Jun. 7, 2010 (KR) 10-2010-0053453

(51) Int. Cl. H01L 21/308; H01L 21/312

(52) U.S. Cl. 438/703; 438/761; 257/E21.231; 257/E21.259

(57) ABSTRACT

Methods of forming a photoresist pattern include forming a first photoresist pattern on a substrate and treating the first photoresist pattern with plasma that modifies etching characteristics of the first photoresist pattern. This modification may include making the first photoresist pattern more susceptible to removal during subsequent processing. The plasma-treated first photoresist pattern is covered with a second photoresist layer, which is patterned into a second photoresist pattern that contacts sidewalls of the plasma-treated first photoresist pattern. The plasma-treated first photoresist pattern is selectively removed from the substrate to reveal the remaining second photoresist pattern. The second photoresist pattern is used as an etching mask during the selective etching of a portion of the substrate (e.g., target layer). The use of the second photoresist pattern as an etching mask may yield narrower linewidths in the etched portion of the substrate than are achievable using the first photoresist pattern alone.

### REFERENCE TO PRIORITY APPLICATION

This application claims priority to Korean Patent Application No. 10-2010-0053453, filed on Jun. 7, 2010, the disclosure of which is hereby incorporated herein by reference in its entirety.

### FIELD

This invention relates to methods of forming photoresist patterns and, more particularly, to methods of forming photoresist patterns using double patterning technology for manufacturing semiconductor devices having minute patterns.

### BACKGROUND

In order to manufacture semiconductor devices having minute patterns of about 30 nm or less, patterning technology to about 30 nm or less may be required. Instead of commonly applied exposing processes using a light source of ArF (193 nm) or KrF (248 nm), a process using extreme ultraviolet radiation (EUV) of about 13 nm technology has attracted much concern as an exposing technology of the next generation. However, mass production using the EUV process has been delayed.

A double patterning technology (DPT) has been suggested as a replacing technology wherein an exposing process may be performed twice or more times to form patterns to accomplish twice times higher resolution with respect to conventionally formed patterns.

The DPT technology may include a double exposing method using a pattern separating process for separating a pattern layout and a spacer processing method using a spacer forming process. The spacer processing method may be applied for the manufacture of a memory device having relatively simple semiconductor pattern shapes. However, as the number of processing steps increase for the formation of the spacer and as the number of equipments increase for manufacturing a memory device having relatively complicated semiconductor patterns, total processing cost may increase. Further, as a pattern size of semiconductor devices shrink and as forming frequency of layers using the DPT increases, manufacturing efficiency of semiconductor devices may decrease.

### SUMMARY

The methods of forming integrated circuit devices frequently include using photolithography processes to define photoresist patterns. According to some embodiments of the invention, methods of forming a photoresist pattern include forming a first photoresist pattern on a substrate and then treating the first photoresist pattern with a plasma that modifies etching and reflectivity characteristics of the first photoresist pattern. This modification of characteristics may include making the first photoresist pattern more susceptible to removal during subsequent processing. The plasma-treated first photoresist pattern is then covered with a second photoresist layer, which is then patterned into a second photoresist pattern that contacts sidewalls of the plasma-treated first photoresist pattern. The first photoresist pattern and the second photoresist pattern may be formed from the same materials. The plasma-treated first photoresist pattern is then selectively removed from the substrate to reveal the remaining second photoresist pattern thereon. The second photoresist pattern is then used as an etching mask during the selective etching of a portion of the substrate (e.g., target layer). The use of the second photoresist pattern as an etching mask may yield narrower linewidths in the etched portion of the substrate than are achievable using the first photoresist pattern alone.

According to some of these embodiments of the invention, the first photoresist pattern and the second photoresist pattern may be formed of a material selected from a group consisting of acrylate polymers, methacrylate polymers, cycloolefin-maleic anhydride copolymers and combinations thereof. The forming of the first photoresist pattern and the patterning of the second photoresist layer may also be performed using the same photolithography mask. In addition, the step of treating may include exposing the first photoresist pattern to a plasma generated from a gas selected from a group consisting of hydrogen bromide, chlorine and argon gases. Moreover, the step of treating may include exposing the first photoresist pattern to the plasma at a pressure in a range from about 3 mTorr to about 5 mTorr and for a duration in a range from 50 seconds to 160 seconds.

According to some of these embodiments of the invention, the selective removal of the plasma-treated first photoresist pattern may be performed by ashing with an oxygen gas. The treating of the first photoresist pattern with a plasma may increase a light reflectivity of the first photoresist pattern relative to the second photoresist pattern. In addition, a width of the second photoresist pattern may be controlled by a time period of the plasma treating and an exposing amount applied during forming the second photoresist pattern.

### BRIEF DESCRIPTION OF THE DRAWINGS

Example embodiments will be more clearly understood from the following detailed description taken in conjunction with the accompanying drawings. FIGS. 1 to 18 represent example embodiments as described herein.

FIGS. 1 to 7 are cross-sectional views for explaining a method of forming a photoresist pattern in accordance with some example embodiments.

FIGS. 8 to 10 are cross-sectional views for explaining a method of manufacturing a DRAM device by applying a method of forming a photoresist pattern in accordance with some example embodiments.

FIGS. 11A and 11B are plan views of a NAND flash memory device manufactured by applying a method of forming a photoresist pattern in accordance with some example embodiments.

FIGS. 12 to 18 are cross-sectional views for explaining a method of manufacturing a NAND flash memory device illustrated in FIGS. 11A and 11B by applying a method of forming a photoresist pattern in accordance with some example embodiments.

### DETAILED DESCRIPTION OF THE EMBODIMENTS

Various example embodiments will be described more fully hereinafter with reference to the accompanying drawings, in which some example embodiments are shown. The present inventive concept may, however, be embodied in many different forms and should not be construed as limited to the example embodiments set forth herein. Rather, these example embodiments are provided so that this description will be thorough and complete, and will fully convey the scope of the present inventive concept to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. The regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of this specification and the relevant art and will not be interpreted in an idealized or overly formal sense unless expressly so defined herein.

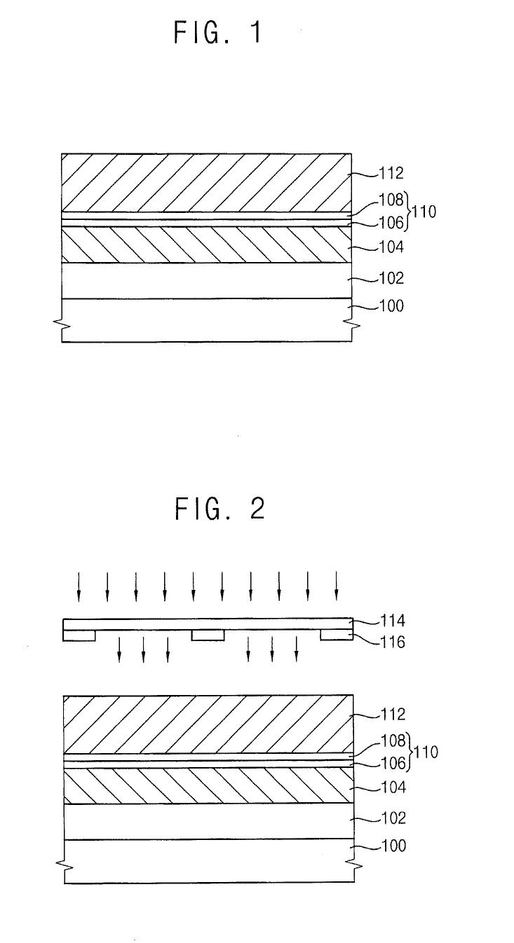

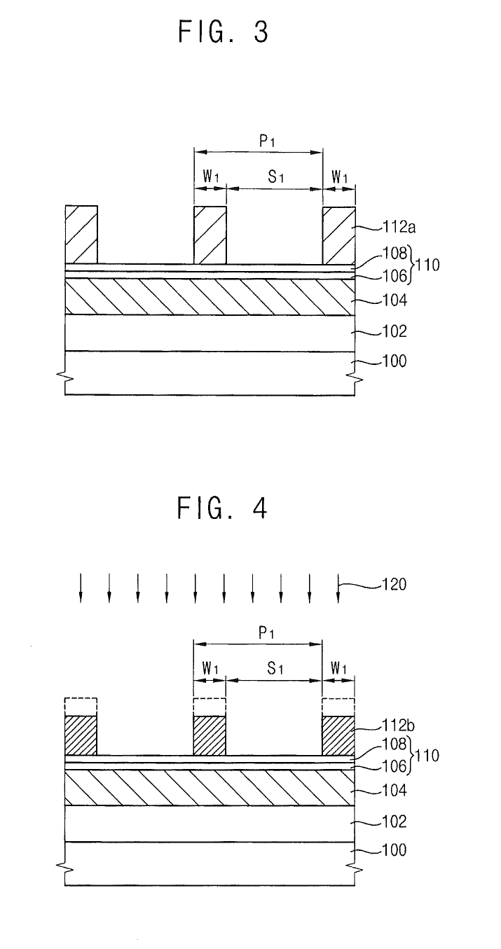

FIGS. 1 to 7 are cross-sectional views for explaining a method of manufacturing a photoresist pattern in accordance with some example embodiments. First, a preliminary first photoresist pattern 112a may be formed on an etching target layer 102 formed on a substrate 100 as illustrated in FIG. 3. The preliminary first photoresist pattern 112a may be formed through the following processes. Referring to FIG. 1, a mask layer 104 may be deposited on the etching target layer 102 formed on the substrate 100. The etching target layer 102 may be a conductive layer or an insulating layer constituting a semiconductor device and may be formed using a metal, a semiconductor or an insulating material. For example, the etching target layer 102 may be formed using tungsten, tungsten silicide, polysilicon, aluminum or a combination thereof. The etching target layer 102 may be also formed using an oxide compound, a nitride compound, an oxynitride compound, etc.

The mask layer 104 may be formed to form a mask pattern for etching the etching target layer 102. The mask layer 104 may be formed using a material having an etching selectivity with respect to the etching target layer 102 and may include polysilicon, an oxide compound, a nitride compound, a metal or a combination thereof. On the mask layer 104, an anti-reflective coating layer 110 may be deposited. The anti-reflective coating layer 110 may be formed to prevent scattering reflection during performing an exposing process for forming a photoresist pattern in a following step and may be formed using an organic material and/or an inorganic material. Particularly, the anti-reflective coating layer 110 may be obtained by successively forming an inorganic anti-reflective coating layer 106 and an organic anti-reflective coating layer 108. The inorganic anti-reflective coating layer 106 may be formed using silicon oxynitride and the organic anti-reflective coating layer 108 may be formed using an anti-reflective coating material. On the anti-reflective coating layer 110, a first photoresist film 112 may be formed to form the preliminary first photoresist pattern.

The first photoresist film 112 may be formed using a material including a chemically amplified resist corresponding to a light source including an ArF-i (193 nm-i) or a vacuum UV (VUV; 147 nm). Particularly, the first photoresist film 112 may be formed using acrylate polymer, methacrylate polymer, cycloolefin-maleic anhydride copolymer (COMA type polymer) of cycloolefin monomers and maleic anhydride, a combination thereof, etc. The first photoresist film 112 may be formed by a spin-on depositing process using the photoresist material. In this case, the first photoresist film 112 may be formed to a thickness to form the preliminary first photoresist pattern 112a (refer to FIG. 3) formed in a following process so that the hard mask layer 104 may be etched using the preliminary first photoresist pattern 112a. Particularly, the photoresist material may be deposited by a spin coating method to form the first photoresist film 112 to a thickness of about 80 nm to about 150 nm.

Referring to FIG. 2, an exposing mask 114 including a chrome pattern 116 may be provided above the first photoresist film 112. A first exposing process to pass light through slits of the chrome pattern 116 of the exposing mask 114 may be performed. The chrome pattern 116 may include a repeatedly formed line shape having a predetermined pitch in a first direction as the preliminary first photoresist pattern 112a to be formed subsequently. The pitch may represent a width of a repeating pattern unit and may be obtained by adding a width of one pattern and a gap between patterns.

Referring to FIG. 3, a first pitch P₁ of the preliminary first photoresist pattern 112a may be obtained by adding a first width W₁ and a first gap S₁ between patterns. The first direction may represent a direction of patterns to be formed from the etching target layer 102.

To manufacture a pattern having about 30 nm or less for a semiconductor device, ArF-i (193 nm-i) or VUV (147 nm) may be used as a light source for performing the first exposing process. Particularly, the first exposing process may be performed using the light source of ArF-i by applying energy of about 10 mJ/cm² to about 40 mJ/cm². According to the kind of the light source, the first width W₁ and the first gap S₁ between the patterns of the preliminary first photoresist pattern 112a may be determined.

In this case, the chrome pattern 116 of the exposing mask 114 may be designed to have a larger pitch than a second pitch P₂ of a second photoresist pattern 124 to be formed (refer to FIG. 6). As the pitch of the chrome pattern 116 is formed to be large, diffracting angle of beams may not be decreased and a high resolution of the patterns may be accomplished.

In accordance with some embodiments, the pitch of the chrome pattern 116 may be designed to have the same size as the first pitch P₁ of the subsequently formed preliminary first photoresist pattern 112a. That is, the width of the chrome pattern 116 of the exposing mask 114 and the gap between the chrome patterns may be designed to have the same first width W₁ of the subsequently formed preliminary first photoresist pattern 112a and the first gap S₁ between the patterns of the preliminary first photoresist pattern 112a.

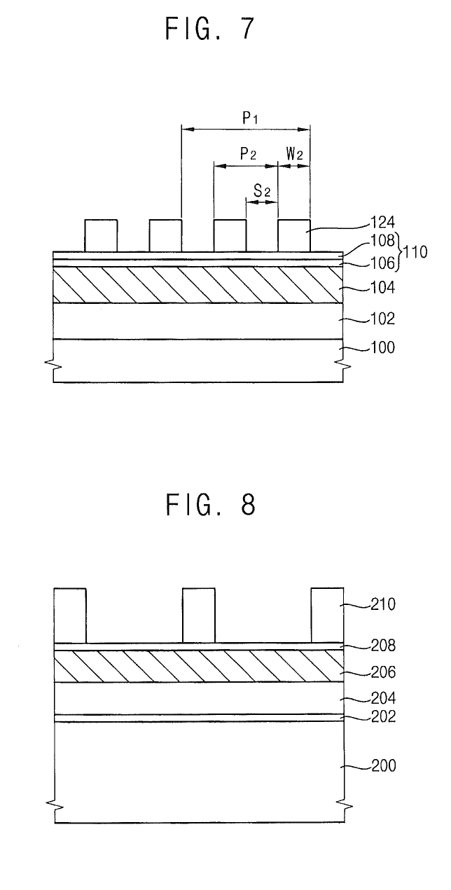

In accordance with some embodiments, the first width W₁ of the subsequently formed preliminary first photoresist pattern 112a and the first gap S₁ between the patterns of the preliminary first photoresist pattern 112a may be formed to have a ratio of about 1:3 so that a second width W₂ and a second gap S₂ of a finally formed second photoresist pattern 124 (refer to FIG. 7) may be repeated. In this case, the width of the chrome pattern 116 of the exposing mask 114 and the gap between the chrome patterns may be designed to have the same ratio of about 1:3 as the first width W₁ and the first gap S₁ of the preliminary first photoresist pattern 112a. That is, the first width W₁ may be designed to have about ¼ of the first pitch P₁. The width of the chrome pattern 116 also may be designed to have about ¼ of the first pitch P₁.

Before performing the first exposing process, a pre-baking process may be performed. Further, after performing the first exposing process, a post-baking process may be also performed. The pre-baking and the post-baking processes may be performed at a temperature of about 80° C. to 110° C.

Referring to FIG. 3 again, a first exposing process may be performed. Then, exposed photoresist region of the first photoresist film 112 may be removed by a first developing process to form a preliminary first photoresist pattern 112a. The first developing process may be performed using an alkaline developing solution of about 2.4% by weight of tetramethyl ammonium hydroxide (TMAH) solution. A crystalline phase may be transformed to an amorphous phase in the exposed photoresist region and the transformed portion of the photoresist into the amorphous phase may be dissolved into the developing solution and removed. Through performing the first developing process, the preliminary first photoresist pattern 112a may include a plurality of line patterns having the first pitch P₁ repeatedly formed in a first direction. As designed for the exposing mask 114, the preliminary first photoresist pattern 112a may be formed to have the first pitch P₁.

In accordance with some embodiments, the first width W₁ of the preliminary first photoresist pattern 112a may be formed to have about ¼ of the first pitch P₁. That is, the first width W₁ and the first gap S₁ of the preliminary first photoresist pattern 112a may be formed to have a ratio of about 1:3. After performing the first developing process using the developing solution, a rinsing process using a rinsing solution to remove the developing solution may be performed. The rinsing solution may include deionized water (DIW).

Referring to FIG. 4, the preliminary first photoresist pattern 112a may be transferred to a dry etching apparatus and a plasma process to expose the preliminary first photoresist pattern 112a to plasma 120 may be performed so as to change a light reflectance of the surface portion of the preliminary first photoresist pattern 112a. Plasma 120 may be a gaseous phase of dissociated ions of positive charge and dissociated electrons of negative charge at a high temperature, Plasma 120 may be obtained using a gas having a high charge dissociating degree and having the same positive and negative charge numbers to exhibit neutral including hydrogen bromide (HBr) gas, chlorine (Cl₂) gas, etc. A mixture gas of the hydrogen bromide (HBr) gas and the chlorine (Cl₂) gas may be also used. Further, a single element molecule having a stable gas at a high temperature including argon (Ar) may be used.

The plasma process may be performed in the dry etching apparatus at a pressure of about 3 mTorr to 5 mTorr for about 50 seconds to 160 seconds to transform the structure of the preliminary first photoresist pattern 112a to an insoluble state in an organic solution. Particularly, the plasma process may be performed using hydrogen bromide (HBr) gas at a pressure of about 3 mTorr to 5 mTorr for about 100 seconds to 150 seconds.

Through the plasma process, double bonds of acrylate or cycloolefin included in the surface portion of the preliminary first photoresist pattern 112a may exhibit negative charges and the negative charges may react with other double bonds to begin a cross-linking reaction at the surface portion of the preliminary first photoresist pattern 112a. Then, crystal structure of the preliminary first photoresist pattern 112a may become dense and the height of the preliminary first photoresist pattern 112a may be reduced while maintaining the line width to form a first photoresist pattern 112b. In accordance with some embodiments, the height of the first photoresist pattern 112b may be reduced by about 10 nm with respect to the height of the preliminary first photoresist pattern 112a. Along with the structural change, the first photoresist pattern 112b may become insoluble into an organic solvent and may show similar or increased light reflecting degree when comparing with the anti-reflective coating layer 110.

In accordance with some embodiments, the plasma process may be performed with respect to the preliminary first photoresist pattern 112a so that the light reflectance of thus formed first photoresist pattern 112b may be higher than the light reflectance of the plasma treated anti-reflective coating layer 108. Particularly, the light reflectance of the first photoresist pattern 112b may be in a range of about 0.25 to 0.30.

In accordance with some embodiments, the light reflectance of the first photoresist pattern 112b may change in accordance with the plasma treating period and exposing amount to the light. The light reflectance may be increased as the plasma treating period increases and may be decreased as the exposing amount increases. Particularly, an optimized light reflectance of the first photoresist pattern 112b may be obtained through the plasma process performed for about 100 seconds to 150 seconds and the exposing process with an exposing amount of about 10 mJ/cm² to about 30 mJ/cm².

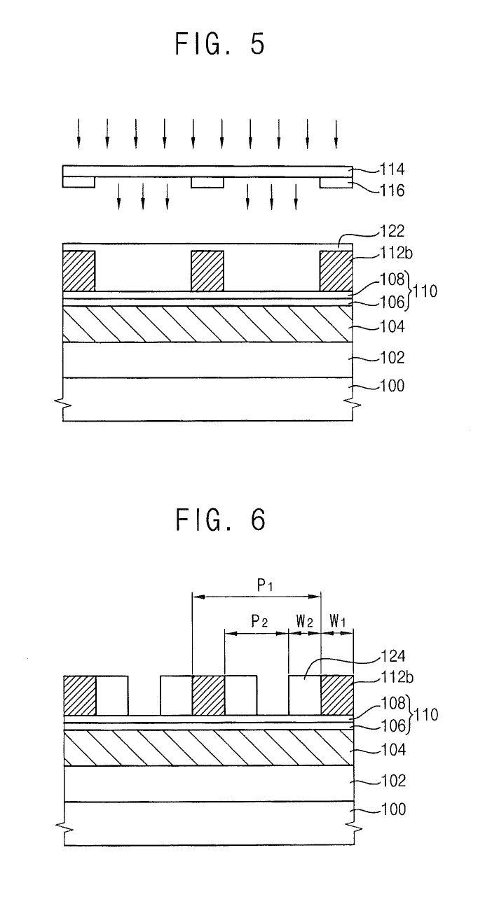

Because of the structural change of the first photoresist pattern 112b through the plasma process, the first photoresist pattern 112b may not be dissolved into an organic solvent used for a spin coating to form a second photoresist film 122 (refer to FIG. 5) in a following process and may remain without changing its shape.

Referring to FIG. 5, a second photoresist film 122 may be formed on the first photoresist pattern 112b and the anti-reflective coating layer 110 to cover the first photoresist pattern 112b. The second photoresist film 122 may be formed using the same material as the first photoresist film 112. The second photoresist film 122 may be formed using a material including chemically amplified resist reactive to a light source of ArF-i (193 nm-i), VUV (147 nm), etc. Particularly, the second photoresist film 122 may be formed using an acrylate polymer, a methacrylate polymer, a copolymer of cycloolefin-based monomer and maleic anhydride (COMA type polymer), a combination thereof, etc. The second photoresist film 122 may be formed by depositing a photoresist material by a spin-on deposition manner to cover the first photoresist pattern 112b. The second photoresist film 122 may be formed by spin coating the photoresist material to have a similar thickness as the first photoresist pattern 112b.

With respect to the second photoresist film 122, a second exposing process may be performed using the exposing mask 114 applied for the first exposing process to pass light through a slit portion of the chrome pattern 116 of the exposing mask 114.

To perform the second exposing process, the same light source used to perform the first exposing process may be used. The second exposing process may be performed using a light source of ArF-i (193 nm-i) or VUV (147 nm). Particularly, the second exposing process may be performed using the ArF-i (193 nm-i) light source with an energy amount of about 10 mJ/cm² to about 50 mJ/cm².

The exposing mask 114 may be the same exposing mask used for performing the first exposing process and the chrome pattern 116 may be designed to have the first pitch P₁ larger than the second pitch P₂ of the second photoresist pattern 124 to be formed in a following process. The light source and the exposing mask 114 applied for the second exposing process may expose the same sites exposed through the first exposing process to form the preliminary first photoresist pattern 112a. In this case, a separate aligning process may not be necessary.

Through the second exposing process, a crystalline state of a portion of the second photoresist film 122 exposed through the exposing mask 114 may change into an amorphous state. In this case, a portion of the second photoresist film 122 above the first photoresist pattern 112b and adjacent to the first photoresist pattern 112b, the light reflectance may increase to make a small change with respect to the crystal state of the second photoresist film 122. At the center portion of the second photoresist film 122 formed between the patterns of the first photoresist pattern 112b, the light may reach to the surface portion of the anti-reflective coating layer 108 by the second exposure. However, at a portion deviated from the center portion of the second photoresist film 122 between the patterns of the first photoresist pattern 112b and near the first photoresist pattern 112b, the incident light may reach to the first photoresist pattern 112b diagonally. Accordingly, transmittance of the exposing light at the interface portion of the first photoresist pattern 112b and the second photoresist film 122 may be lowered.

At an interface portion of the first photoresist pattern 112b and the second photoresist film 122, an optical characteristic of the second photoresist film 122 may change and the crystallinity of the second photoresist film 122 by the exposure may not change sufficiently.

In accordance with some embodiments, the second exposing process with respect to the second photoresist film 122 may be performed through controlling the exposing amount onto the second photoresist film 122 so that a second photoresist pattern 124 to be formed in a following process may have a desired second width W₂. The exposing amount may be controlled so that the second photoresist pattern 124 to be formed in a following process may have the same width as the first width W₁ of the first photoresist pattern 112b.

A pre-baking process may be performed before the second exposing process and a post-baking process may be also performed after the second exposing process. These baking processes may be performed at a temperature range of about 90° C. to 110° C.

Referring to FIG. 6, after performing the second exposing process, the exposed photoresist region may be removed by a developing process to form the second photoresist pattern 124 remaining at both side wall portions of the plasma treated first photoresist pattern 112b. The developing process may be performed using an alkaline developing solution of TMAH solution of about 2.4% by weight. A crystalline state of the exposed photoresist region may change into an amorphous state and may be removed through a reaction with the developing solution. A portion of the second photoresist film 122 of which physical properties may remain unchanged may remain as the second photoresist pattern 124 on the anti-reflective coating layer 108 after performing the exposing process. A portion of the second photoresist film 122 exposed to the light may remain after performing the forming process of the second photoresist pattern 124. Particularly, the second width W₂ of the second photoresist pattern 124 may be the same as the first width W₁ of the first photoresist pattern 112b. After performing the developing process using the developing solution, a rinsing process using a rinsing solution to remove the developing solution may be performed. The rinsing solution may include DIW.

As described above, the second photoresist pattern 124 may adhere to and remain on both side wall portions of the first photoresist pattern 112b after performing the second exposing process using the same exposing mask 114 used for performing the first exposing process. Optical properties of the first photoresist pattern 112b may change after performing the plasma process and optical properties of a portion of the second photoresist film 122 adjacent to the first photoresist pattern 112b may change after performing the second exposing process. Accordingly, the crystalline state of the portion of the second photoresist film 122 may not change by the second exposing process.

In accordance with some embodiments of forming photoresist patterns, the second width W₂ of the second photoresist pattern 124 between the patterns of the first photoresist pattern 112b may be adjusted by controlling a plasma treating period and an exposing amount. Therefore, minute line widths of the finally formed second photoresist pattern 124 may be controlled.

Referring to FIG. 7, the first photoresist pattern 112b may be selectively removed. The removal of the first photoresist pattern 112b may be performed by an ashing process using oxygen (O₂) gas. The ashing process may be performed by supplying O₂ gas in an amount of about 5 sccm to about 30 sccm to completely remove the plasma treated first photoresist pattern 112b. On the substrate 100 including the etching target layer 102 thereon, a plurality of the second photoresist pattern 124 may remain with a constant distance between the patterns of the second photoresist pattern 124. A plurality of the patterns of the second photoresist pattern 124 may include a plurality of minute line patterns repeatedly formed to a predetermined direction with a second pitch P₂ smaller than the first pitch P₁.

Using the second photoresist pattern 124 repeatedly formed with the second pitch P₂ as an etching mask, the exposed anti-reflective coating layer 110 and the mask layer 104 may be etched to form an anti-reflective coating layer pattern (not shown) and a mask pattern (not shown). Then, the exposed etching target layer 102 may be anisotropically etched using the mask pattern to form a semiconductor device including repeatedly formed patterns or wirings with a minute pitch on the substrate 100.

In accordance with some embodiments of forming a photoresist pattern, patterns having minute pitch overcoming a resolution limit may be formed using the commonly used light source and a photo process applying the double patterning technology. Particularly, double patterning technology may be performed using the same exposing mask for performing twice times of exposing processes and a high resolution under about 30 nm may be accomplished. Further, additional cost for aligning, for controlling process conditions or for using a CVD equipment may be reduced to increase productivity of a semiconductor device process.

Hereinafter, methods of manufacturing semiconductor memory devices including a DRAM device, a NAND flash memory device, etc. by applying methods of forming a photoresist pattern in accordance with example embodiments may be explained in brief.

FIGS. 8 to 10 are cross-sectional views for explaining a method of manufacturing a DRAM device by applying a method of forming a photoresist pattern in accordance with some example embodiments. Referring to FIG. 8, a gate insulating layer 202 may be formed on a substrate 200. The gate insulating layer 202 may be formed using silicon oxide. On the gate insulating layer 202, a gate electrode layer 204 may be formed. The gate electrode layer 204 may be formed by a chemical vapor deposition process using polysilicon. The gate electrode layer 204 may be formed by a plasma enhanced chemical vapor deposition process using a material having a low electric resistance including tungsten, tungsten nitride, etc. The gate electrode layer 204 may be provided as a gate electrode in a following process. On the gate electrode layer 204, a hard mask layer 206 may be formed. The hard mask layer 206 may be formed using silicon oxide. The hard mask layer 206 may be provided as an etching mask for forming the gate electrode in a following process. On the hard mask layer 206, an anti-reflective coating layer 208 may be formed. The anti-reflective coating layer 208 may be formed as an inorganic anti-reflective coating layer, an organic anti-reflective coating layer or an integrated layer of them. The anti-reflective coating layer 208 may be provided to shield a reaction of the gate electrode layer 204 with the exposing light during forming the photoresist pattern in a following process.

A first photoresist film may be formed on the anti-reflective coating layer 208 and a first exposing process with respect to the first photoresist film and a developing process may be performed to form a preliminary first photoresist pattern 210. The preliminary first photoresist pattern 210 may have a line shape extended in a predetermined direction. The preliminary first photoresist pattern 210 may be formed using a chemically amplified resist material applicable for a light source of ArF-i (193 nm-i) or VUV (147 nm).

The preliminary first photoresist pattern 210 may be formed to have a first width W₁ and a first gap S₁ in a ratio of about 1:3 so that a ratio of a second width W₂ and a second gap S₂ of a second photoresist pattern to be formed in a following process and to remain on both side wall portions of the first photoresist pattern may be about 1:1. The first width W₁ of the preliminary first photoresist pattern 210 may be the same as the second width W₂ of the finally formed second photoresist pattern. The first width W₁ may be about ¼ of the first pitch P₁.

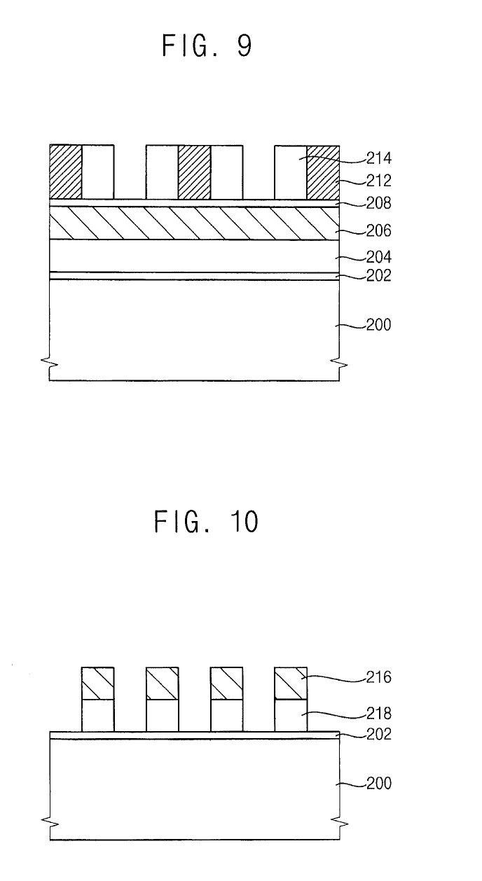

Referring to FIG. 9, a plasma process using hydrogen bromide (HBr) gas as a plasma gas may be performed with respect to the preliminary first photoresist pattern 210 to form a first photoresist pattern 212 which may have a different light reflectance. The chemical bonding structure of the first photoresist pattern 212 may change to increase the number of double bonds by the plasma treatment. Therefore, the first photoresist pattern 212 may not be removed by an organic solvent during performing a spin coating process for forming a second photoresist film in a following process but may remain.

The light reflectance of the preliminary first photoresist pattern 210 may change after performing the plasma process and thus formed first photoresist pattern 212 may exhibit a different light reflectance. Further, physical properties of a portion of the first photoresist pattern 212 may not change during performing the second exposing in a following process. The condition of the plasma treatment may be determined so that the light reflectance of the first photoresist pattern 212 may be higher than the light reflectance of the plasma treated anti-reflective coating layer 208. The plasma process with respect to the preliminary first photoresist pattern 210 may be performed by exposing to a plasma gas under a pressure range of about 3 mTorr to 5 mTorr for about 50 seconds to 160 seconds. After performing the plasma process, the width of the first photoresist pattern 212 may not change but the height of the first photoresist pattern 212 may be slightly reduced when comparing with the preliminary first photoresist pattern 210.

A second photoresist film (not shown) covering the anti-reflective coating layer 208 and the first photoresist pattern 212 may be formed. A second exposing process using the exposing mask applied for the first exposing process and a developing process may be performed with respect to the second photoresist film (not shown) to form a second photoresist pattern 214 remaining on both side wall portions of the first photoresist pattern 212. In this case, the second photoresist pattern 214 may be repeatedly formed so that a ratio of a second width W₂ and a second gap S₂ of the second photoresist pattern 214 may be about 1:1. The second photoresist pattern 212 may be provided as an etching mask for patterning the hard mask layer 206 in a following process.

The second photoresist pattern 214 may also have an extended line shape in the same direction as the first photoresist pattern 212. The second photoresist pattern 214 may be formed using the same material as the first photoresist pattern 210. The second exposing process may be performed using the same exposing mask as the first exposing process and so, the same sites may be exposed through the second exposing process as the first exposing process. However, physical properties of a portion among the exposed second photoresist film may change and remain to form the second photoresist pattern 214.

Referring to FIG. 10, the first photoresist pattern 212 may be removed by performing an ashing process using oxygen (O₂) gas. The anti-reflective coating layer 208 and the hard mask layer 206 may be etched using the second photoresist pattern 214 as an etching mask to form an anti-reflective coating layer pattern (not shown) and a hard mask pattern 216. The second photoresist pattern 214 and the anti-reflective coating layer pattern may be removed by performing an ashing process. The gate electrode layer 204 may be etched using the hard mask pattern 216 as an etching mask to form a gate electrode 218. Then, impurities may be doped into the substrate 200 around the gate electrode 218 to form source/drain regions. A MOS transistor including the gate electrode 218 and the source/drain regions may be formed on the substrate 200.

The gate electrode 218 of the MOS transistor included in a DRAM device may include a repeatedly formed line and space structure and the width of each line and space may be very narrow. Accordingly, the gate electrode may be formed using the double patterning technology in accordance with some example embodiments. The gate electrode having a minute pitch of about 30 nm or less may be formed without performing an aligning process or re-controlling process conditions during performing a photo process.

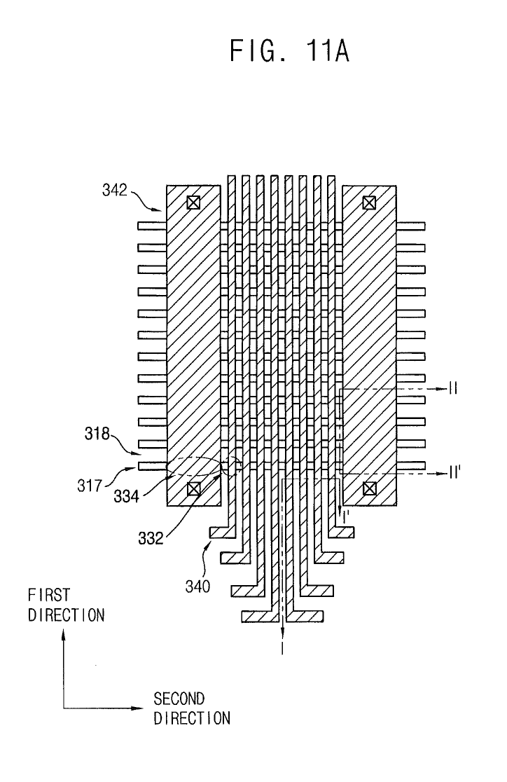

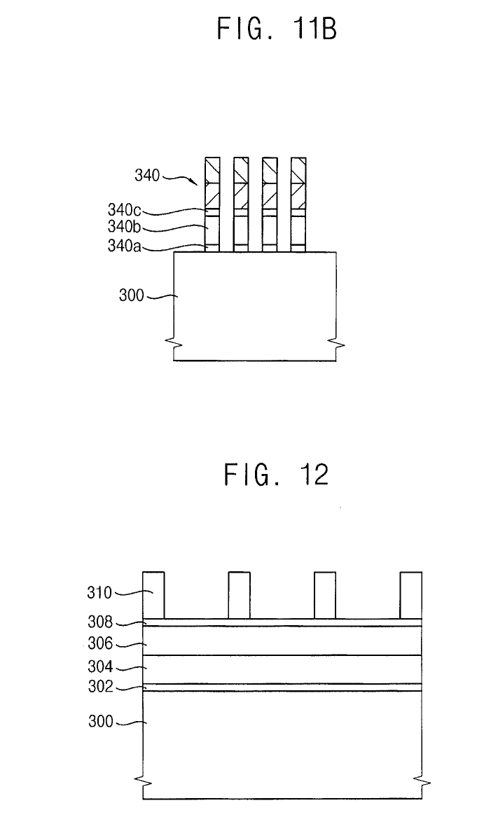

FIGS. 11A and 11B are plan views of a NAND flash memory device manufactured by applying a method of forming a photoresist pattern in accordance with some example embodiments. FIG. 11B is a cross-sectional view cut along a line I-I′ in FIG. 11A, Referring to FIGS. 11A and 11B, the upper surface portion of the single crystalline silicon substrate 300 may be divided into an active region for forming circuits and a device isolation region for electrically separating each device. The active region may include an active pattern 317 which may have a line shape extended in a second direction and may be repeatedly provided. The active pattern 317 may have a narrow line width up to the limit line width, which may be formed by means of a photo process. Between the active patterns 317, trenches may be provided and insulating materials may fill up the trenches to form a device isolating layer pattern 318.

On the active pattern 317, a cell transistor 332, a word line 340 and a selecting transistor 334 may be formed. The cell transistor 332 may include a tunnel oxide layer pattern 340a, a floating gate electrode 340b, a dielectric layer pattern 340c and a control gate electrode 340. Particularly, the tunnel oxide layer pattern 340a may be provided on the surface portion of the active pattern 317. The floating gate electrode 340b may have an isolated pattern shape and may be regularly provided on the tunnel oxide layer pattern 340a. On the floating gate electrode 340a, the dielectric layer pattern 340c may be provided. The control gate electrode 340 provided on the dielectric layer pattern 340c may have a line shape extended in a first direction perpendicular to the second direction and may face the floating gate electrode 340b provided there under. The control gate electrode 340 may be commonly used as the word line 340.

In the NAND flash memory device, the device isolation layer pattern and the control gate electrode may have a line shape and a repeating pattern shape. Accordingly, the forming process of the photoresist pattern in accordance with example embodiments may be applied as the patterning process for forming the device isolation layer pattern and the control gate electrode. FIGS. 12 to 18 are cross-sectional views for explaining a method of manufacturing a NAND flash memory device illustrated in FIGS. 11A and 11B by applying a method of forming a photoresist pattern in accordance with some example embodiments. FIGS. 12 to 16 are cross-sectional views obtained when cut along a line II-II′ in FIG. 11A and FIGS. 17 and 18 are cross-sectional views obtained when cut along a line I-I′ in FIG. 11A.

Referring to FIG. 12, a tunnel oxide layer 302 may be formed on a substrate 300. The tunnel oxide layer 302 may be formed through a thermal oxidation of the substrate 300. A first gate electrode layer 304 may be formed on the tunnel oxide layer 302. The first gate electrode layer 304 may be formed using polysilicon by means of a low pressure chemical vapor deposition process. The first gate electrode layer 304 may be provided as a floating gate electrode in a following process. A hard mask layer 306 may be formed on the first gate electrode layer 304. The hard mask layer 306 may be formed using silicon oxide. The hard mask layer 306 may be provided as an etching mask for separating an active region and a device isolation region in a following process. An anti-reflective coating layer 308 may be formed on the hard mask layer 306. The anti-reflective coating layer 308 may include an inorganic anti-reflective coating layer, an organic anti-reflective coating layer or an integrated layer of them. The anti-reflective coating layer 308 may be provided to shield a reaction of the first gate electrode layer 304 with an exposing light during performing a forming process of a photoresist pattern in a following process.

A first photoresist film (not shown) may be formed on the anti-reflective coating layer 308 and a first exposing process using an exposing mask and a developing process may be performed with respect to the first photoresist film to form a preliminary first photoresist pattern 310. The preliminary first photoresist pattern 310 may have a line shape extended in a second direction which is the same extended direction of the active region. The preliminary photoresist pattern 310 may be formed using a material including a chemically amplified resist for a light source of ArF-i (193 nm-i) or VUV (147 nm). A first width W₁ and a first gap S₁ of the preliminary first photoresist pattern 310 may be about 1:3 so that a second width W₂ and a second gap S₂ of a second photoresist pattern to be formed in a following process and remaining at both side wall portions of the first photoresist pattern may be about 1:1. The first width W₁ of the preliminary first photoresist pattern 310 may be the same as the second width W₂ of the second photoresist pattern and a first pitch P₁ may be about ¼.

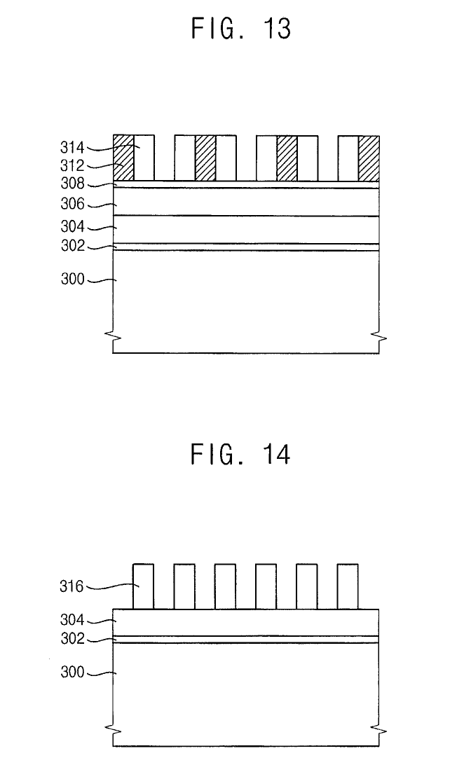

Referring to FIG. 13, a plasma treating process using a plasma gas such as hydrogen bromide (HBr) gas, chlorine (Cl₂) gas, argon (Ar) gas or a mixture of them may be performed with respect to the preliminary first photoresist pattern 310, to form a first photoresist pattern 312 of which light reflectance may change. The bonding structure of the first photoresist pattern 312 may change and numbers of double bonds may increase through the plasma treatment. Accordingly, the first photoresist pattern 312 may not be removed but may remain by an organic solvent during performing a spin coating process for forming a second photoresist film in a following process.

Through the plasma treating process, the light reflectance of the first photoresist pattern 312 may change so that physical properties of a portion of the exposed photoresist during performing the second exposing process for forming the second photoresist pattern may not change. After performing the plasma treating process, the light reflectance of the first photoresist pattern 312 may become higher than the light reflectance of the plasma treated anti-reflective coating layer 308. The plasma treating process with respect to the preliminary first photoresist pattern 310 may be performed by exposing to a plasma gas under a pressure of about 3 mTorr to about 5 mTorr for about 50 seconds to about 160 seconds. Through the plasma treating process, the width of the first photoresist pattern 312 may not change but the height of the first photoresist pattern 312 may be reduced to a certain degree when comparing with the preliminary first photoresist pattern 310.

After forming a second photoresist film (not shown) covering the anti-reflective coating layer 308 and the first photoresist pattern 312, a second exposing process with respect to the second photoresist film may be performed using the same exposing mask applied for the first exposing process. Then, a developing process may be performed to form a second photoresist pattern 314 remaining at both side wall portions of the first photoresist pattern 312. The second photoresist pattern 314 may be formed to have a ratio of the second width W₂ and the second gap S₂ of the second photoresist pattern 314 may be about 1:1. The second photoresist pattern 314 may be provided as an etching mask for patterning the hard mask layer 306 in a following process. The second photoresist pattern 314 may also have a line shape extended in a second direction as the first photoresist pattern 312. The second photoresist pattern 314 may be formed using the same material as the preliminary first photoresist pattern 310. When the same sites in the second photoresist pattern 314 are exposed during the second exposing as the first exposing, physical properties of a portion of the exposed second photoresist film may change. The changed second photoresist pattern 314 may not be removed but remain after performing the developing process.

Referring to FIG. 14, the first photoresist pattern 312 may be removed by an ashing process using oxygen (O₂) gas. The anti-reflective coating layer 308 and the hard mask layer 306 may be etched using the second photoresist pattern 314 as an etching mask to form an anti-reflective coating layer pattern (not shown) and a hard mask pattern 316. The second photoresist pattern 314 and the anti-reflective coating layer pattern may be removed.

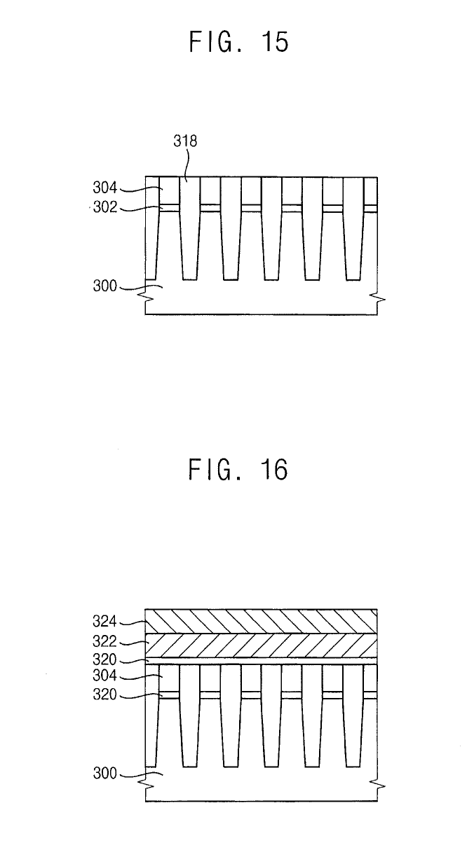

Referring to FIG. 15, the first gate electrode layer 304, the tunnel oxide layer 302 and a surface portion of the substrate 300 may be etched using the hard mask pattern 316 as an etching mask to form a trench. Then, an insulating material may fill up the trench and a chemical mechanical polishing process may be performed to form a device isolating layer pattern 318. Most of the hard mask pattern 316 may be removed during the polishing process. Remaining hard mask pattern 316 may be removed. The single crystalline silicon substrate may be divided into an active region and a device isolating region.

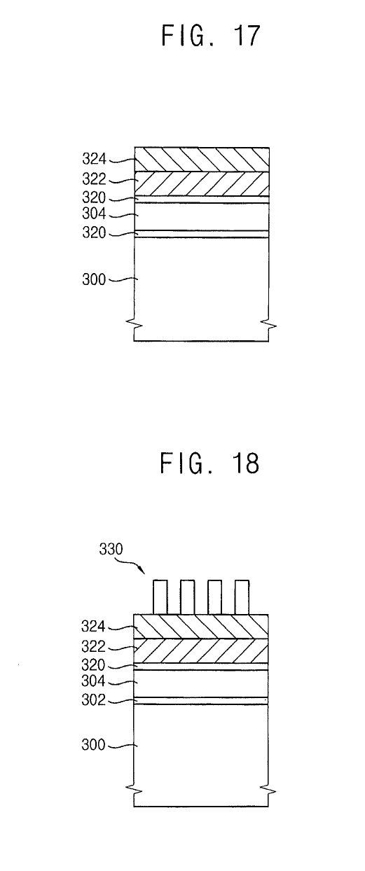

Referring to FIGS. 16 and 17, a dielectric layer 320 and a second gate electrode layer 322 may be formed on the first gate electrode layer 304 and the device isolating layer pattern 318. An insulating layer for hard mask 324 may be formed on the second gate electrode layer 322. The insulating layer for hard mask 324 may be provided as an etching target layer.

Referring to FIG. 18, a spacer pattern 330 extended in a first direction perpendicular to the second direction may be formed on the insulating layer for hard mask 324. The spacer pattern 330 may be provided for forming a mask pattern for forming the control gate electrode 340 of the cell transistor 332 and the gate electrode 342 of the selecting transistor 334. The control gate electrode 340 of the cell transistor 332 may be commonly used with the word line. The spacer pattern 330 may be formed by the same double patterning process applied for the second photoresist pattern 314. A preliminary photoresist pattern may be formed on the insulating layer for hard mask 324 through performing a first patterning process and a plasma treating process using HBr gas. A second patterning process may be performed to form the spacer pattern 330 of the photoresist having a desired width and gap at both side portions of the preliminary photoresist pattern. In this case, the width of the spacer pattern 330 and the gap between the patterns may be controlled to be the same.

The insulating layer for hard mask 324 may be etched using the spacer pattern 330 to form an etching mask pattern. The underlying second gate electrode layer 322 may be etched using the etching mask pattern and then, the dielectric layer 320 and the first gate electrode layer 304 may be successively etched.

The control gate pattern 340 of the cell transistor and the gate pattern 342 of the selecting transistor 334 may be formed as illustrated in FIGS. 11A and 11B. Under the control gate pattern 340, a dielectric layer pattern 340c and a floating gate pattern 340b may be formed.

In accordance with some embodiments, a device isolating layer pattern, a second photoresist pattern for etching a mask pattern for forming a control gate pattern and a spacer pattern may be formed by a double patterning process using the same light source and the same exposing mask. During performing a photo process for forming minute patterns of about 30 nm or less, aligning or re-adjusting process may not required to decrease a manufacturing cost.

As described above, a spacer for self aligning may be formed by performing a double patterning process using the same exposing mask in a photo process in accordance with some example embodiments. A high resolution may be accomplished for patterns having about 30 nm or less and an aligning process or a re-adjusting of process conditions may not be required. Additional processing cost accompanied by using an ALD equipment, a CVD equipment may be decreased and productivity of a semiconductor device of about 30 nm or less may be effectively improved.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

1. A method of forming a photoresist pattern, comprising:
forming a first photoresist pattern on a substrate;
treating the first photoresist pattern with a plasma that modifies etching characteristics of the first photoresist pattern;
covering the plasma-treated first photoresist pattern with a second photoresist layer;
patterning the second photoresist layer into a second photoresist pattern that contacts sidewalls of the plasma-treated first photoresist pattern;
selectively removing the plasma-treated first photoresist pattern from the substrate to reveal the second photoresist pattern thereon; and
selectively etching a portion of the substrate using the second photoresist pattern as an etching mask.

2. The method of claim 1, wherein the first photoresist pattern and the second photoresist pattern comprise the same materials.

3. The method of claim 2, wherein the first photoresist pattern and the second photoresist pattern comprise a material selected from a group consisting of acrylate polymers, methacrylate polymers, cycloolefin-maleic anhydride copolymers and combinations thereof.

4. The method of claim 1, wherein the first photoresist pattern and the second photoresist pattern each comprise a material selected from a group consisting of acrylate polymers, methacrylate polymers, cycloolefin-maleic anhydride copolymers and combinations thereof.

5. The method of claim 1, wherein said treating comprises exposing the first photoresist pattern to a plasma generated from a gas selected from a group consisting of hydrogen bromide, chlorine and argon gases.

6. The method of claim 5, wherein said treating comprises exposing the first photoresist pattern to the plasma at a pressure in a range from about 3 mTorr to about 5 mTorr and for a duration in a range from 50 seconds to 160 seconds.

7. The method of claim 1, wherein said forming a first photoresist pattern and said patterning the second photoresist layer are performed using the same photolithography mask.

8. The method of claim 7, wherein said selectively removing the plasma-treated first photoresist pattern comprises removing the plasma-treated first photoresist pattern by ashing with an oxygen gas.

9. The method of claim 2, wherein said treating comprises treating the first photoresist pattern with a plasma that increases a light reflectivity of the first photoresist pattern relative to the second photoresist pattern.

10. The method of claim 1, wherein said forming a first photoresist pattern comprises developing a first photoresist layer using a 2.4% by weight of a tetramethyl ammonium hydroxide (TMAH) solution.

11. A method of forming a photoresist pattern comprising:
forming a preliminary first photoresist pattern on a substrate including an etching target layer;
plasma treating the preliminary first photoresist pattern to form a first photoresist pattern;
forming a second photoresist pattern at both side portions of the first photoresist pattern; and
removing the first photoresist pattern.

12. The method of forming a photoresist pattern of claim 11, wherein the preliminary first photoresist pattern and the second photoresist pattern are formed using a same material.

13. The method of forming a photoresist pattern of claim 11, wherein the preliminary first photoresist pattern and the second photoresist pattern are formed using at least one selected from the group consisting of an acrylate polymer, a methacrylate polymer, a cycloolefin-maleic anhydride copolymer and a hybrid polymer thereof.

14. The method of forming a photoresist pattern of claim 11, wherein the preliminary first photoresist pattern has a line shape and a plurality of patterns of the preliminary first photoresist pattern is extended in one direction.

15. The method of forming a photoresist pattern of claim 11, wherein the plasma treating is performed using at least one plasma gas selected from the group consisting of hydrogen bromide (HBr) gas, chlorine (Cl₂) gas and argon (Ar) gas.

16. The method of forming a photoresist pattern of claim 15, wherein the plasma treating is performed by exposing the preliminary first photoresist pattern to the plasma gas under a pressure of about 3 mTorr to about 5 mTorr for about 50 seconds to about 160 seconds.

17. The method of forming a photoresist pattern of claim 11, wherein a light reflectance of the first photoresist pattern after performing the plasma treating is higher than a light reflectance of a plasma treated anti-reflective coating layer.

18. The method of forming a photoresist pattern of claim 11, wherein a same exposing mask is used for forming the first photoresist pattern and the second photoresist pattern.

19. The method of forming a photoresist pattern of claim 11, wherein a width of the second photoresist pattern is controlled by a time period of the plasma treating and an exposing amount applied during forming the second photoresist pattern.

20. The method of forming a photoresist pattern of claim 11, wherein the first photoresist pattern is removed by an ashing process using oxygen (O₂) gas.

21.-28. (canceled)
